(19) United States
(12) Patent Application Publication
(10) Pub. No.: US 2007/0123027 A1
(43) Pub. Date: May 31, 2007

(54) Wiring forming method, wiring forming apparatus, and wiring board

(76) Inventors: Michinori Shinkai, Kanagawa-ken (JP); Satoshi Suzuki, Kanagawa-ken (JP)

Correspondence Address: MORGAN & FINNEGAN, L.L.P., 3 WORLD FINANCIAL CENTER, NEW YORK, NY, 10281-2101, US

(21) Appl. No.: 10/582,920

(22) PCT Filed: Dec. 20, 2004
(86) PCT No.: PCT/JP04/19486

§ 371 Date: Jun. 13, 2006

(30) Foreign Application Priority Data
Dec. 22, 2003 (JP) 2003-424990

(51) Int. Cl. H01L 21/4763; B05C 11/00

(52) U.S. Cl. 438/622; 118/663

(57) ABSTRACT

After performing one forming step of a first pattern forming step of forming a first patent on a substrate and a second pattern forming step of forming a second pattern on the substrate, the other forming step is performed to thereby form, a high-reliability wiring pattern on the substrate.

### TECHNICAL FIELD

The present invention relates to a wiring forming method, a wiring forming apparatus, and a wiring board.

### BACKGROUND ART

In general, wirings have been formed in a printed wiring board by a subtractive method. The wirings are formed by the subtractive method through a hole making step, an electroless plating step, a patterning step by a dry film or the like, an electrolytic plating step, an etching step, a solder peeling step and the like. The number of the steps is large, much time is required for each step, and a ratio of a processing cost in a manufacturing cost is high. Especially, when a multilayered wiring board is formed, the reduction of the processing cost raises a large problem. There is also a problem of treatment of waste liquids generated in the plating step or the etching step.

To solve these problems, a method of manufacturing the printed wiring board has been described in Japanese Patent Application Laid-Open No. H11-163499 in which a conductive pattern and an insulated pattern are formed on the surface of a substrate at the same time by an ink jet system.

FIG. 20 is a sectional view of a wiring board in a conventional example. Since a conductive pattern A and an insulated pattern B are formed on a substrate 301 at the same time, it is difficult to separate the conductive pattern A from the insulated pattern B. Since the conductive pattern A spreads on the substrate, as shown in FIG. 20, the conductive patterns contact each other, the wirings short-circuit, and it has been difficult to form a wiring having high reliability.

### DISCLOSURE OF THE INVENTION

A main object of the present invention is to solve problems of a conventional technique and to provide a wiring forming method, a wiring forming apparatus, and a wiring board capable of forming a wiring pattern having high reliability.

### BRIEF DESCRIPTION OF THE DRAWINGS

FIG. 1 is a sectional view of a wiring board in the present invention;

FIG. 2 is a perspective view showing a main part of a wiring forming apparatus by an ink jet system according to one embodiment of the present invention;

FIG. 3 is a schematic block diagram showing a system constitution of the wiring forming apparatus of the present invention;

FIGS. 4A, 4B, and 4C are constitution diagrams showing control of a substrate receiving portion in a height direction in the present invention, 4A is a constitution diagram showing the control of the substrate receiving portion in the height direction, 4B is a diagram showing a state in which the substrate receiving portion is in an uppermost stage, and 4C is a diagram showing a state in which the substrate receiving portion is in a lowermost stage;

FIGS. 5A and 5B are constitution diagrams showing the control of a head in the height direction in the present invention, 5A is a diagram of a control section viewed from a transverse direction of a substrate, and 5B is a diagram viewed from an upper direction of the substrate;

FIGS. 6A and 6B are diagrams showing a wiring pattern of a lamination structure in the present invention, 6A is a diagram of the wiring pattern of the lamination structure viewed downwards from the substrate upper direction, and 6B is a sectional view along VIB-VIB of FIG. 6A;

FIGS. 7-1, 7-2, 7-3, 7-4, 7-5 and 7-6 are diagrams showing wiring forming steps in Example 2 of the present invention;

FIG. 8 is a flowchart of a program of the wiring forming step in Example 2 of the present invention;

FIGS. 9-1, 9-2, 9-3, 9-4, 9-5, 9-6 and 9-7 are diagrams showing wiring forming steps in Example 3 of the present invention;

FIGS. 10-8, 10-9, 10-10 and 10-11 are diagrams showing wiring forming steps continued from the steps of FIGS. 9-1 to 9-7 in Example 3 of the present invention;

FIGS. 11-1, 11-2, 11-3, 11-4, 11-5 and 11-6 are diagrams showing wiring forming steps in Example 4 of the present invention;

FIGS. 12-7, 12-8, 12-9, 12-10, 12-11 and 12-12 are diagrams showing wiring forming steps continued from the steps of FIGS. 11-1 to 11-6 in Example 4 of the present invention;

FIG. 13 is a flowchart showing control of a size of an insulated pattern in Example 5 of the present invention;

FIG. 14 which is composed of FIGS. 14A and 14B are flowcharts showing a procedure to perform a heating/curing process of the wiring pattern in Example 6 of the present invention;

FIGS. 15-1, 15-2, 15-3, 15-4, 15-5 and 15-6 are diagrams showing the wiring forming steps in Example 7 of the present invention;

FIG. 16 which is composed of FIGS. 16A and 16B are flowcharts showing a procedure of the wiring forming step in Example 7 of the present invention;

FIGS. 17-1, 17-2, 17-3, 17-4, 17-5, 17-6 and 17-7 are diagrams showing the wiring forming steps in Example 8 of the present invention;

FIG. 18 is a sectional view of a case where a wiring pattern is formed on a substrate having permeability in Example 9 of the present invention;

FIG. 19 is a sectional view of a case where the wiring pattern is formed on a substrate having a convex portion in Example 9 of the present invention;

FIG. 20 is a sectional view of a wiring board in a conventional example; and

FIG. 21 is a diagram showing a step of forming an organic EL in Example 11 of the present invention.

### BEST MODE FOR CARRYING OUT THE INVENTION

An example will be described in which a wiring pattern is formed using semiconductor mask information as printing information, a first pattern is formed as an insulated pattern containing an insulating material, and a second pattern is formed as an electrically conductive pattern containing an electrically conductive material.

FIG. 2 is a perspective view showing a main part of a wiring forming apparatus by an ink jet system which is one of embodiments of the present invention.

Conveying members 2 of a substrate, and conveying members 3 of a head are controlled in accordance with wiring pattern (instruction pattern and/or electrically conductive pattern) forming information instructed from a data processing device 1, and a first liquid in a first liquid container 5 is discharged from an insulated pattern forming head 4 to thereby form the insulated pattern in the substrate on a substrate receiving portion 9. A second liquid in a second liquid container 7 is discharged from a conductive pattern forming head 6 to thereby form the conductive pattern in the substrate. By these steps, the wiring pattern is formed. When the steps are repeated, a wiring board is formed. When the wiring is formed using the ink jet system, a fine wiring having a wiring width of about several to several tens of micrometers can be formed. The first liquid forming the insulated pattern preferably contains inorganic materials such as SiO₂, Al₂O₃, and TiO₂, and organic materials such as polyimide and the like, and the second liquid forming the conductive pattern contains metal materials such as solder, Pt, Ag, Au, In, Ga. A heating/curing device 8 has a purpose of heating/curing the wiring pattern (the insulated pattern and/or the conductive pattern) formed on the substrate, or volatilizing a solvent by a radiant heat source such as an infrared lamp or a xenon lamp. Heat treatment conditions depend on curing conditions of components capable of being heated/cured in the wiring pattern forming liquid (the first liquid and/or the second liquid), but are usually set in such a manner that the wiring pattern portion of the substrate is at temperature of 80 to 150° C. When the substrate is formed of a material capable of withstanding heat treatment, it is also possible to use a method of bringing a resistor into contact with the substrate to heat the whole substrate. When there is a possibility that properties of a wiring pattern forming material or a substrate material change by the heat treatment, the device is structured in such a manner as to have a function of radiating heat from the substrate and the wiring pattern forming portion and cooling them. Furthermore, the wiring pattern portion is cured by light irradiation instead of the heat treatment, or by both the irradiation and the heat treatment depending on the material of the wiring pattern forming liquid. A wavelength for use in the light irradiation has a range in which photo-curable components in the wiring pattern forming liquid have practical sensitivity. For use in a photo reaction mode, in general, a range of 200 nm to 600 nm in an ultraviolet/visible region is used. As a light source, for example, a discharge tube of a mercury lamp, xenon lamp, fluorescent lamp or the like is used.

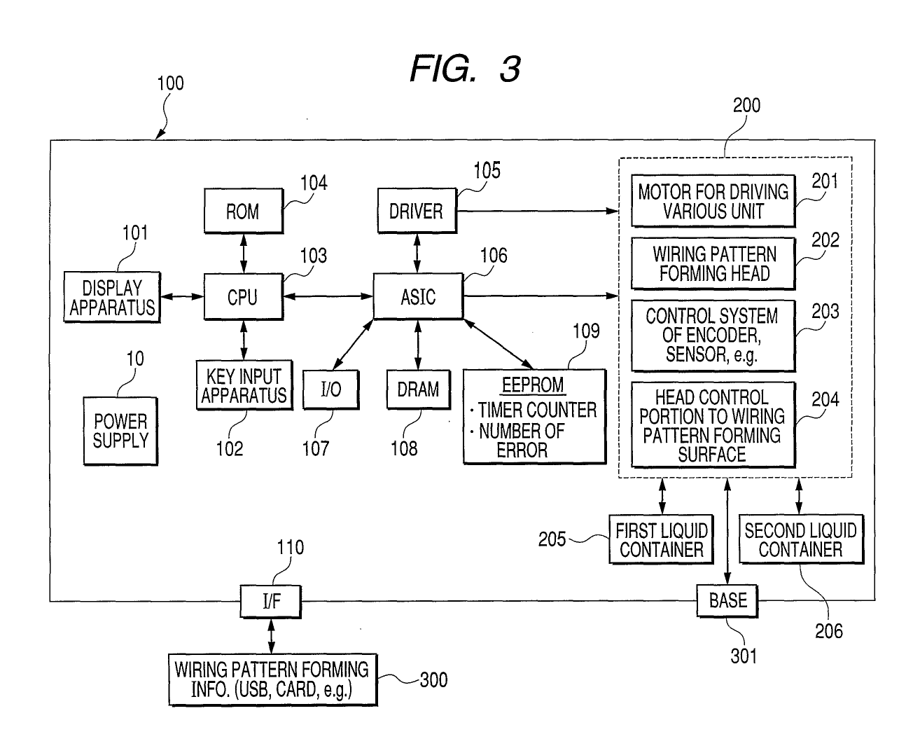

FIG. 3 is a schematic block diagram showing a system constitution of the wiring forming apparatus of the present invention.

Reference numeral 100 denotes a wiring forming apparatus. The apparatus comprises: a CPU 103 which controls hardware of this wiring forming apparatus; an ASIC 106; a ROM 104 in which program to execute a software process is stored; a key input apparatus 102 for selecting an image to be printed; a memory DRAM 108 for developing wiring pattern forming information instructed to be printed and/or converting control of the head into information in forming the wiring; a display apparatus 101 for displaying a display status of the head or the like to a user; a wiring forming apparatus driver 105 for driving a wiring forming apparatus unit 200; a data input I/F 110 which is an entrance for taking in wiring pattern forming information 300 or the like received from the outside; and an I/O 107 for controlling other inputs/outputs.

Moreover, the wiring forming apparatus unit 200 comprises: a motor 201 for driving various units of the wiring forming apparatus; a wiring pattern forming head 202; a control system 203 of an encoder, sensor and the like, which executes the above-described control; a control portion 204 which controls the head in such a manner as to move up/down the head with respect to a wiring pattern forming surface; a first liquid container 205 for storing the first liquid; a second liquid container 206 for storing the second liquid; a substrate 301 on which the wiring pattern is to be formed; and an EEPROM 109 for storing information (information of a recovering operation, a remaining amount of the wiring pattern forming liquid and the like) required for controlling the wiring forming apparatus. The information of the wiring pattern to be formed is acquired from the wiring pattern forming information 300, and the acquired information is temporarily stored in the DRAM 108 which is storage means via the I/F portion 110. This information is converted into the wiring pattern forming information using a part of a memory area in the DRAM.

To form the wiring pattern, the following information is required:

height information of each layer;

definition (minimum line width, minimum line interval, etc.) of X, Y directions;

definition (interval, etc. during superimposition) in case of the superimposition in the X, Y directions; and

grid size of drawings in X, Y directions. The wiring pattern is formed based on the information. That is, when X, Y coordinate values of a position where the wiring pattern is to be formed in a main scanning direction are known, the wiring pattern can be formed.

Moreover, with regard to a pattern width, a pattern length and the like, the information is used as mask information because the X, Y coordinates are known beforehand as described above.

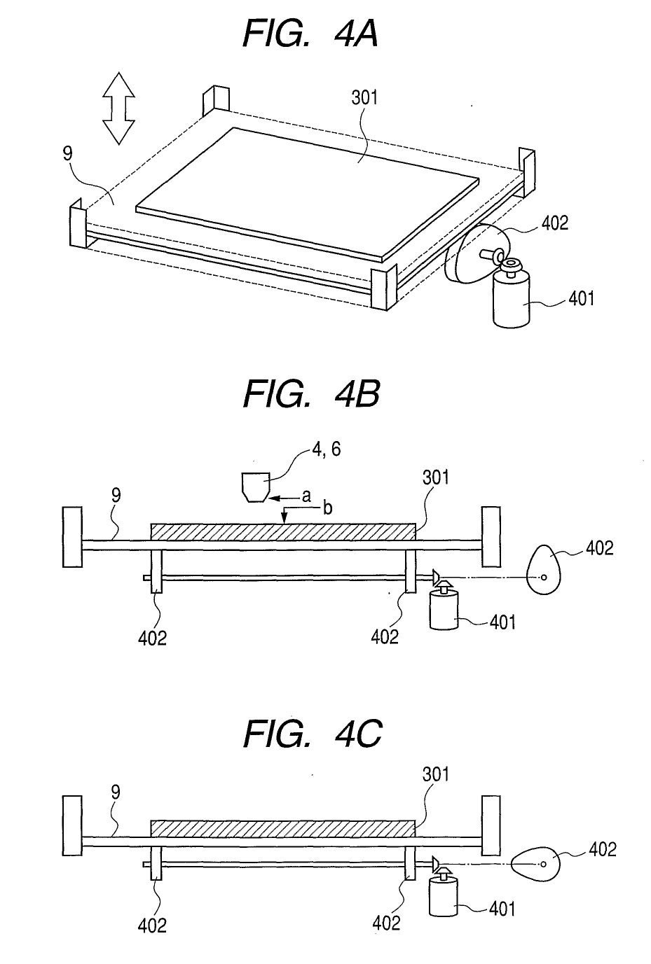

FIGS. 4A to 4C are diagrams showing a method of adjusting height of the substrate receiving portion 9 according to one of the embodiments of the present invention. FIG. 4A is a diagram showing that the substrate receiving portion is controlled in a height direction. FIG. 4B is a diagram showing a state in which the substrate receiving portion is in an uppermost stage. FIG. 4C is a diagram showing a state in which the substrate receiving portion is in a lowermost stage.

A cam 402 is disposed under the substrate receiving portion 9, a motor 401 is rotated in accordance with thickness of the wiring pattern on the substrate to thereby move up/down the substrate receiving portion 9, and accordingly a distance between a discharge port surface a of a printing head (the insulated pattern forming head 4 or the conductive pattern forming head 6) and a wiring pattern forming surface b is kept to be constant. The wiring pattern forming surface b refers to the surface of the substrate 301 disposed in the substrate receiving portion 9, on which the wiring pattern is to be formed. The surface is not limited to the surface of the substrate 301, and refers to the upper surface of the already formed wiring pattern, on which the wiring pattern is to be formed in the case of a lamination structure.

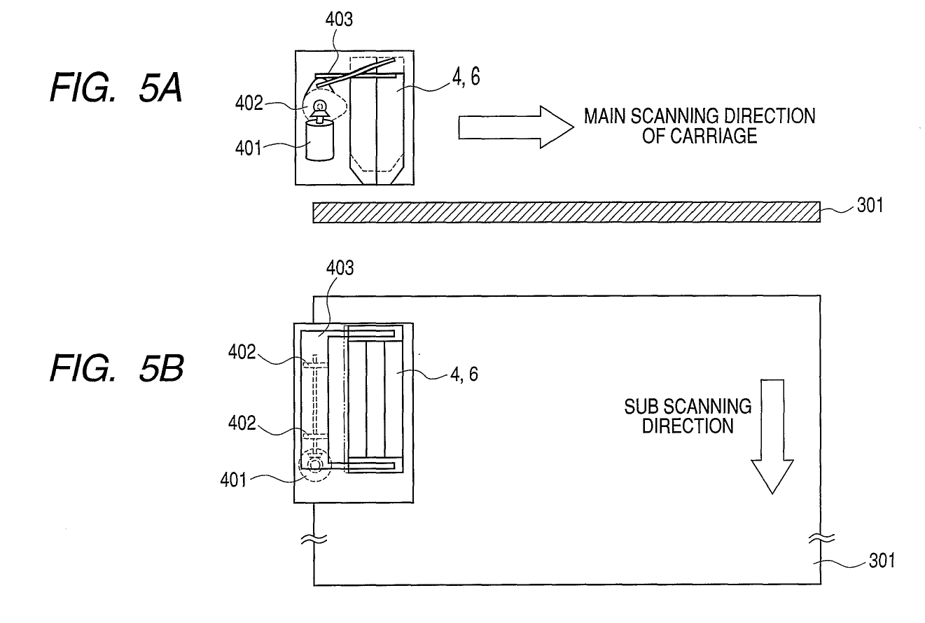

FIGS. 5A, 5B are constitution diagrams showing that a head portion is controlled in the height direction according to one of the embodiments of the present invention. FIG. 5A is a diagram of a control section viewed from a transverse direction of the substrate. FIG. 5B is a diagram viewed from an upper direction of the substrate. As one method for keeping a certain distance between the discharge port surface of the printing head and the wiring pattern forming surface, the head portion is moved up/down and accordingly controlled. A motor 401 and a cam 402 are disposed in the printing head (the insulated pattern forming head 4 and the conductive pattern forming head 6), and the head moves up/down using a spring 403 which moves up/down by an operation of the cam 402. In this constitution, the motor and the cam operate, and the discharge port surface of the head moves up/down by information of a printing layer on which the wiring pattern is to be formed in such a manner that the distance between the discharge port surface of the printing head (the insulated pattern forming head 4 and the conductive pattern forming head 6) and the wiring pattern forming surface is constant.

A method of forming the wiring pattern using the above-described wiring forming apparatus will be described in the following examples, but the present invention is not limited to these examples.

### EXAMPLE 1

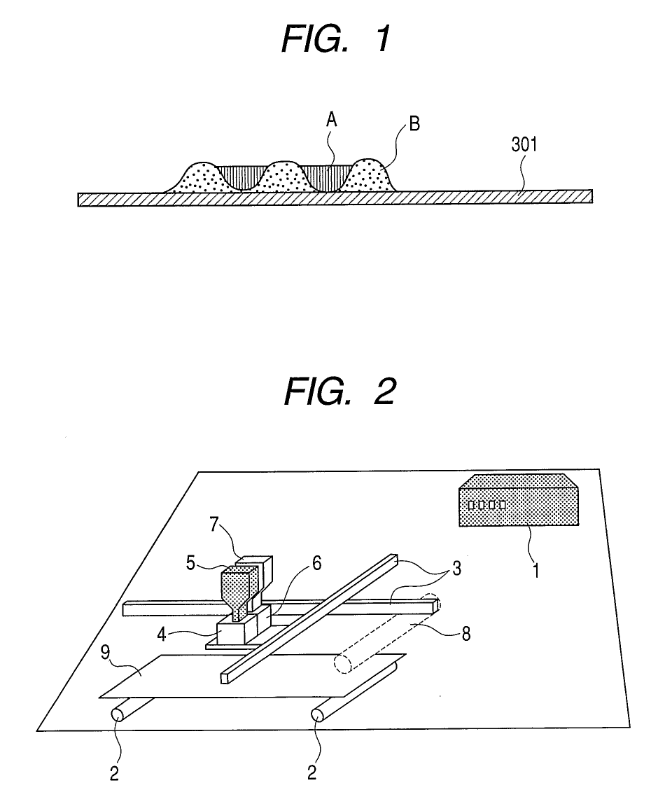

An example in which an insulated pattern is formed prior to a conductive pattern to thereby form a single-layer wiring pattern will be described. A printing buffer capable of storing at least discharge data of a head with respect to a substrate for one scan as printing information is disposed, the data is read from the buffer, and first and second liquids are discharged. FIG. 1 is a sectional view of a wiring board in the present invention. After forming insulated patterns B formed of the first liquid in a plurality of places, a conductive pattern A formed of the second liquid is formed between the insulated patterns B. Since the previously formed insulated pattern B functions as an edge of the conductive pattern A, the conductive pattern A does not spread on the substrate, the conductive patterns are prevented from being brought into contact with each other, and accordingly a wiring is prevented from being short-circuited.

### EXAMPLE 2

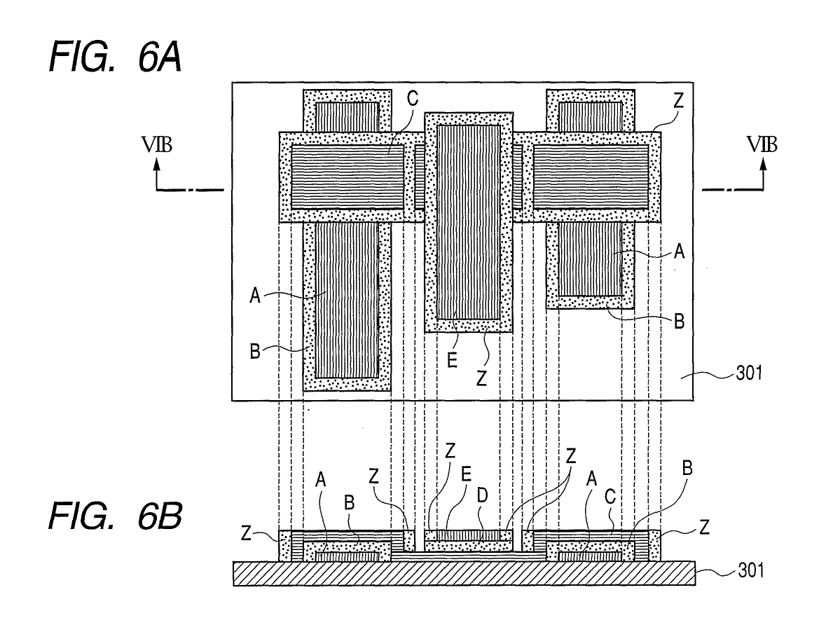

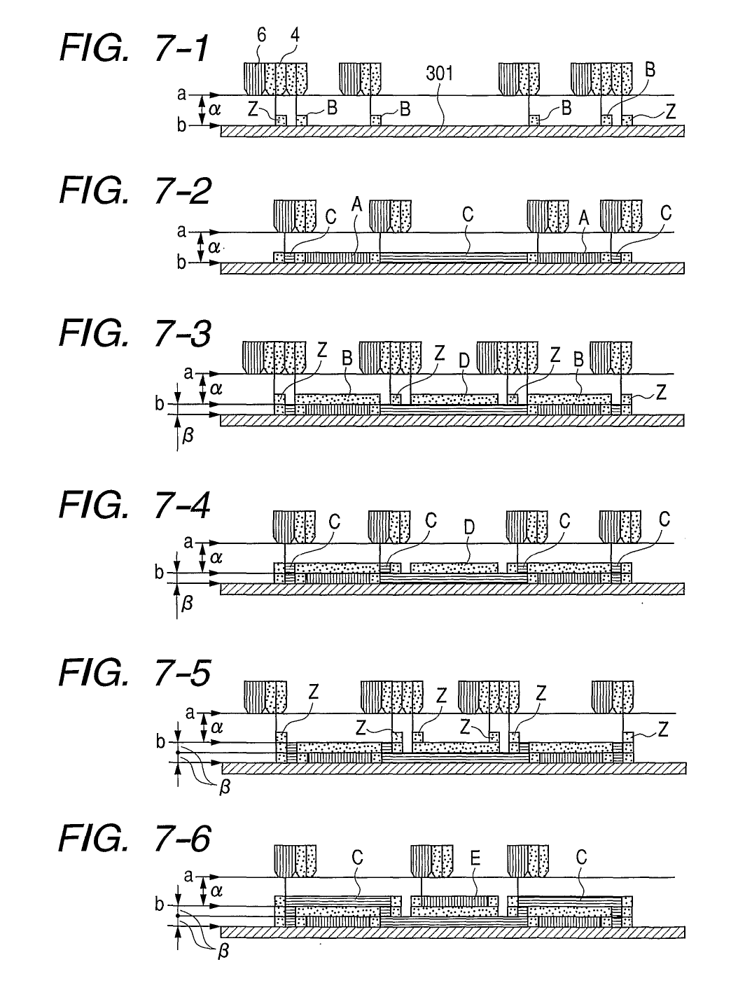

FIGS. 6A, 6B are diagrams showing wirings having a lamination structure in the present invention. The diagrams are schematic in such a manner that a structure of stacked layers of insulated and conductive patterns is clearly shown.

The wiring of the lamination structure is formed by the insulated and conductive patterns superimposed stacked on a substrate. FIG. 6A is a diagram of the wiring pattern of the lamination structure viewed downwards from a substrate upper direction. FIG. 6B is a sectional view along VIB-VIB of FIG. 6A.

Pattern A is a conductive pattern corresponding to a first layer of a mask pattern and having a vertical direction;

B is an insulated pattern corresponding to a second layer of the mask pattern and having the vertical direction;

C is a conductive pattern corresponding to a third layer of the mask pattern and having a transverse direction;

D is an insulated pattern corresponding to a fourth layer of the mask pattern and having the vertical direction;

E is a conductive pattern corresponding to a fifth layer of the mask pattern and having the vertical direction; and

Z is an insulated pattern disposed in order to inhibit short-circuit of the conductive pattern.

With regard to printing information, a printing buffer capable of storing at least discharge data for one scan of a head with respect to the substrate is disposed, and data is read from the buffer to discharge first and second liquids. The information is converted into information for each printing layer by height information based on mask information of each layer. Since the height information of one layer is defined by a design rule, X, Y position information and the portion of the corresponding layer are calculated, and accordingly the information can be converted into the information for each printing layer. Processes for scanning the head to form the wiring will be described as a method of forming the wiring having the lamination structure shown in FIGS. 6A, 6B using the information for each layer obtained by the above-described calculation with reference to FIGS. 7-1 to 7-6.

FIGS. 7-1 to 7-6 are diagrams showing wiring forming steps according to one of embodiments of the present invention. The insulated pattern and the conductive pattern are schematically shown in such a manner as to clarify the structure of the lamination of the patterns. A substrate receiving portion is moved up/down by a motor and a cam as shown in FIGS. 4A to 4C to thereby control a distance between the discharge port surface of the head and the wiring pattern forming surface b into a certain distance a. It is assumed that the head moves to the right from the left, insulated patterns B, D are formed by insulated pattern information included in wiring pattern information, and insulated patterns Z are disposed in such a manner as to inhibit the conductive patterns from being short-circuited.

In FIG. 7-1, to form the wiring pattern of a first layer of a printing layer, the distance between the discharge port surface a of the head and the wiring pattern forming surface b is set to a, and insulated patterns B and Z are formed in the vicinity of positions where the conductive patterns are to be formed.

In FIG. 7-2, after finishing the forming of the insulated patterns, conductive patterns C and A are formed between the insulated patterns, accordingly the insulated patterns are inhibited from being spread, the short-circuit of the wiring is prevented, and it is possible to form a wiring having high reliability. In these steps, the first layer of the printing layer is formed.

Subsequently, a wiring pattern corresponding to a second layer of a printing layer is formed based on data converted from the mask information.

In FIG. 7-3, since the distance between the discharge port surface a of the head and the wiring pattern forming surface b is shorter by a height β by the wiring pattern of the first layer, the motor is rotated to thereby move the substrate receiving portion downwards. To set the distance between the discharge port surface a of the head and the wiring pattern forming surface b corresponding to the second layer of the printing layer to α, a distance between the head and the substrate is adjusted into α+β, and the insulated patterns B, D, Z are formed.

In FIG. 7-4, after finishing the forming of the insulated pattern, conductive patterns C are formed, and the forming of the second layer of the printing layer is completed.

In FIG. 7-5, a wiring pattern of a third layer of the printing layer is formed. Since the distance between the discharge port surface a of the head and the wiring pattern forming surface b is shorter by a height β by the wiring pattern of the second layer, the motor is rotated to thereby move the substrate receiving portion downwards. To set the distance between the discharge port surface a of the head and the wiring pattern forming surface b corresponding to the third layer of the printing layer to α, the distance between the head discharge port surface and the substrate is adjusted into α+β, and the insulated patterns Z are formed.

In FIG. 7-6, after finishing the forming of the insulated pattern, conductive patterns C and E are formed between the insulated patterns Z, and the forming of the wiring pattern is completed.

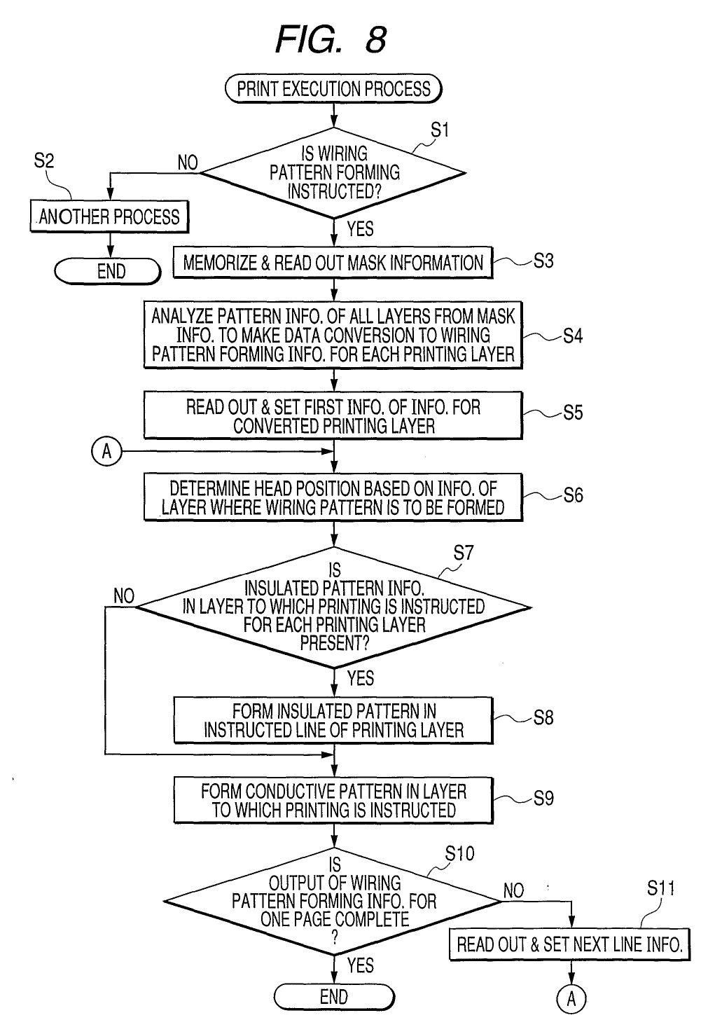

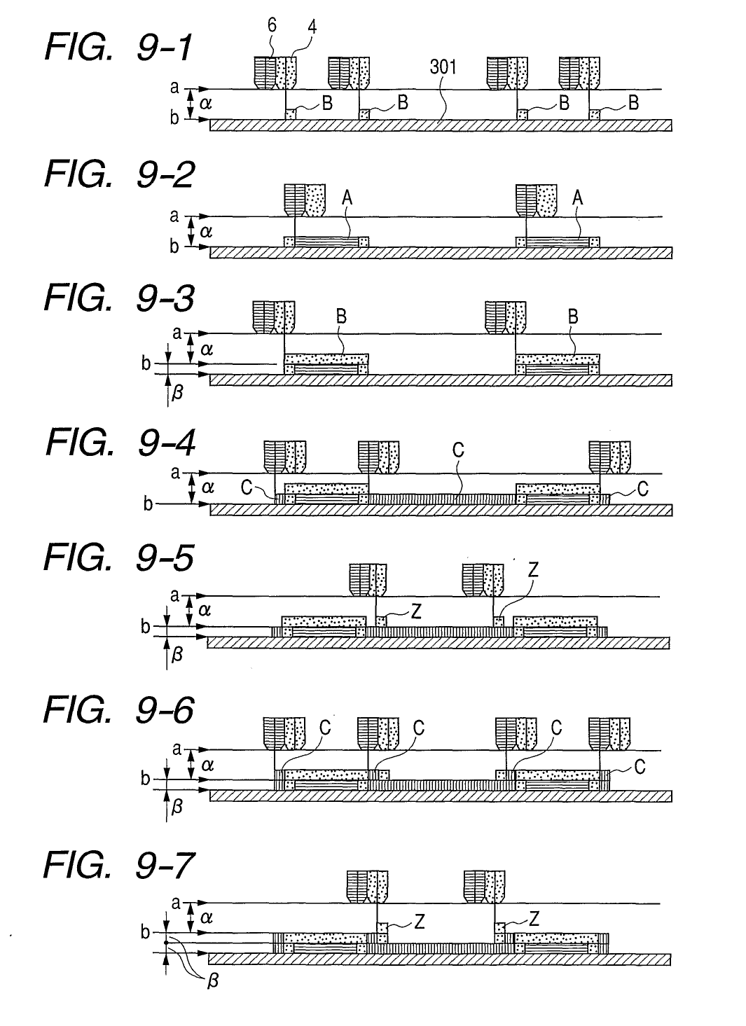

FIG. 8 shows a flowchart of a program of the wiring forming step, stored in the ROM 104 of FIG. 3. It is judged in step S1 whether or not the printing for forming the wiring pattern has been instructed. When there is not any printing instruction, another process is executed and completed in step S2. When there is a printing instruction, the data (mask information for semiconductor printing in the present example) instructed to be printed is read out and stored in a memory in step S3. In step S4, pattern information of all layers is analyzed from the acquired mask information, and the data is converted into wiring pattern forming information for each printing layer. Here, the converted information is stored in memory means of a main body, and the wiring pattern is formed based on the wiring pattern forming information for each printing layer. In step S5, the wiring pattern forming information to be first executed is read out from the information for each printing layer, which was converted in the step S4, and the data is set. In step S6, the position of the head is determined based on the wiring pattern forming information of a layer where the wiring pattern is to be formed. It is judged in step S7 whether or not insulated pattern information is present in the layer in which the previously analyzed information for each printing layer is instructed to be printed. When the insulated pattern information is not included, the step jumps to step S9. When the insulated pattern information is included, the step advances to step S8. The insulated pattern information included in the instructed line of the printing layer is set to form the insulated pattern (corresponding to the forming of the insulated pattern of FIG. 7-1). In step S9, the conductive pattern is formed in the layer instructed to be printed (FIG. 7-2), and the output of the wiring pattern forming information corresponding to the first layer of the printing layer ends. It is judged in step S10 whether or not the output of the wiring pattern forming information for one page has been completed. That is, it is judged whether or not the wiring pattern is continued to be formed for each instructed line to complete the forming of the wiring pattern to the last line. When the forming of the wiring pattern for one page is completed, all the acquired wiring pattern information has been output, and all the processes end. When the process for forming the wiring pattern for one page is not completed, in step S11, line information next to the information by which the wiring pattern has been formed is read out and set, and the process returns to the step S6. When the flow continues, the information acquired by the wiring forming apparatus using the ink jet system can be appropriately output to the substrate.

### EXAMPLE 3

In Example 2, the example has been described in which the mask information is converted into the information for each printing layer, and thereafter the output is obtained using the information for each printing layer. In the present example, a process for obtaining an output in accordance with the mask information to form a wiring will be described. FIGS. 9-1 to 9-7, 10 are diagrams showing wiring forming steps according to one of embodiments of the present invention. Insulated and conductive patterns are schematically shown in such a manner as to clarify a structure of lamination of the patterns. As shown in FIGS. 4A to 4C, a substrate receiving portion is moved up/down by a motor and a cam to thereby control a distance between a discharge port surface a of a head and a wiring pattern forming surface b into a certain distance α. It is assumed that the head moves to the right from the left, insulated patterns B, D are formed by insulated pattern information included in wiring pattern information, and insulated patterns Z are insulated patterns for inhibiting the conductive patterns from being short-circuited. In Example 2, the insulated patterns are disposed on opposite sides of each of the conductive patterns, but in the present example, an example will be described in which the insulated patterns Z are formed only in portions having a high possibility of causing short-circuit of the wiring by the spread conductive patterns.

In FIG. 9-1, the distance between the discharge port surface a of the head and a substrate 301 is set to α. To form a wiring pattern in accordance with the mask information, first a first layer of a printing layer of the insulated pattern B corresponding to a second layer of a mask pattern is formed. In FIG. 9-2, after completing the forming of the insulated patterns B, a conductive pattern A corresponding to a first layer of the mask pattern is formed.

In FIG. 9-3, the motor is rotated to move the substrate receiving portion downwards by a head β for one layer of the wiring pattern, and the distance between the discharge port surface a of the head and the substrate is adjusted into α+β in order to set the distance between the discharge port surface a of the head and the wiring pattern forming surface b to α. A second layer of a printing layer of each insulated pattern B corresponding to the second layer of the mask pattern is formed, and the forming of the second layer of the mask pattern is completed.

In FIG. 9-4, the distance between the discharge port surface a of the head and the wiring pattern forming surface b is set to α, and a first layer of a printing layer of each conductive pattern C corresponding to a third layer of the mask pattern is formed.

In FIG. 9-5, the distance between the discharge port surface a of the head and the substrate is set to α+β, and insulated patterns Z are formed in order to prevent short-circuit of the conductive pattern in the second layer of the printing layer of the conductive pattern C corresponding to the third layer of the mask pattern. In FIG. 9-6, the second layer of the printing layer of each conductive pattern C corresponding to the third layer of the mask pattern is formed.

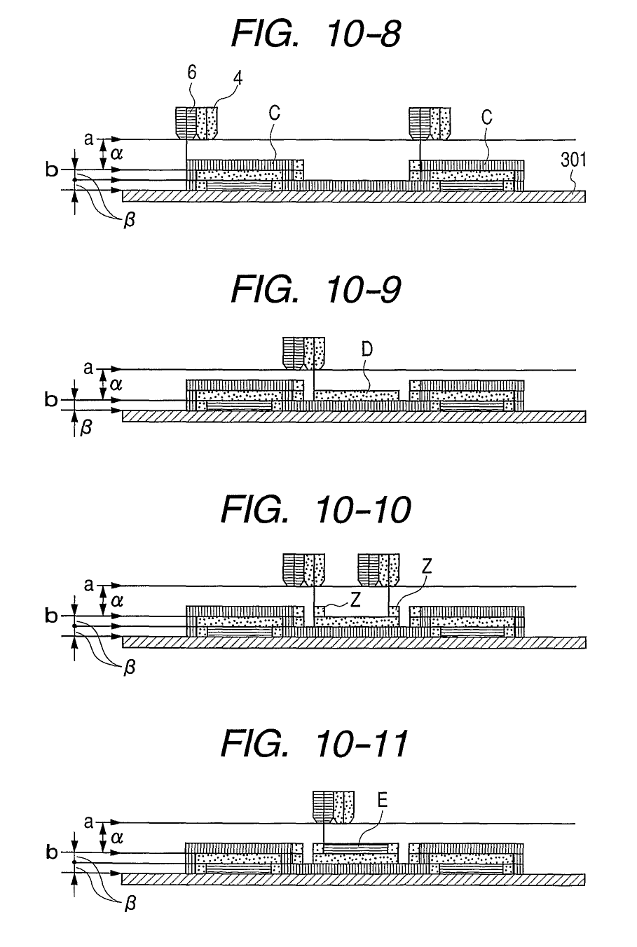

In FIG. 9-7, the distance between the discharge port surface a of the head and the substrate is set to α+2β, and insulated patterns Z are formed in order to prevent the short-circuit of the wiring of the conductive pattern in the third layer of the printing layer of the conductive pattern C corresponding to the third layer of the mask pattern. In FIG. 10-8, a third layer of the printing layer of each conductive pattern C corresponding to the third layer of the mask pattern is formed, and the output of the information up to the third layer of the mask pattern is completed.

In FIG. 10-9, the distance between the discharge port surface a of the head and the substrate is set to α+β, and the insulated pattern D corresponding to a fourth layer of the mask pattern is formed.

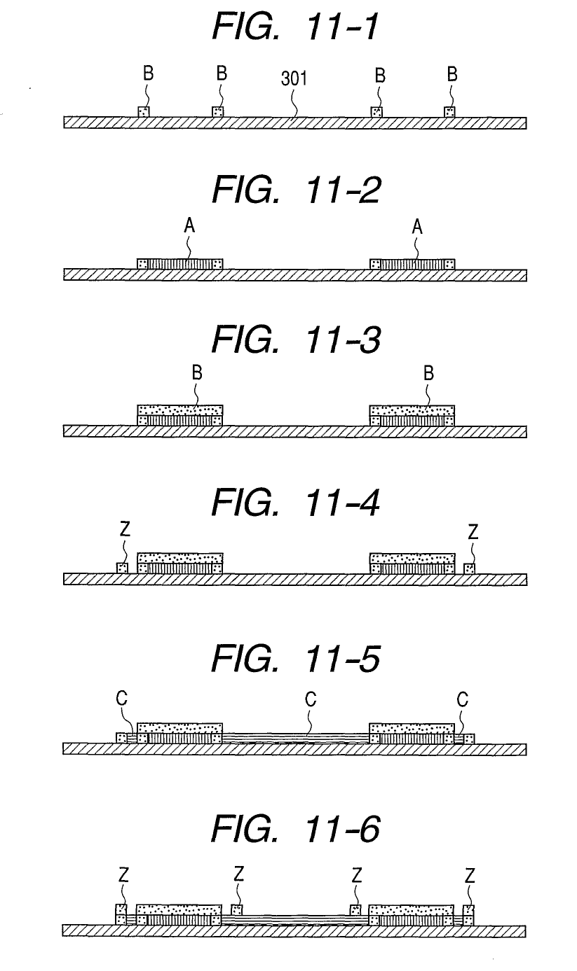

In FIG. 10-10, the distance between the discharge port surface a of the head and the substrate is set to α+2β, and insulated patterns Z are formed in order to prevent the short-circuit of a conductive pattern E to be subsequently formed. Thereafter, the conductive pattern E corresponding to a fifth layer of the mask pattern is formed, and the forming of the wiring pattern is completed (FIG. 10-11).

### EXAMPLE 4

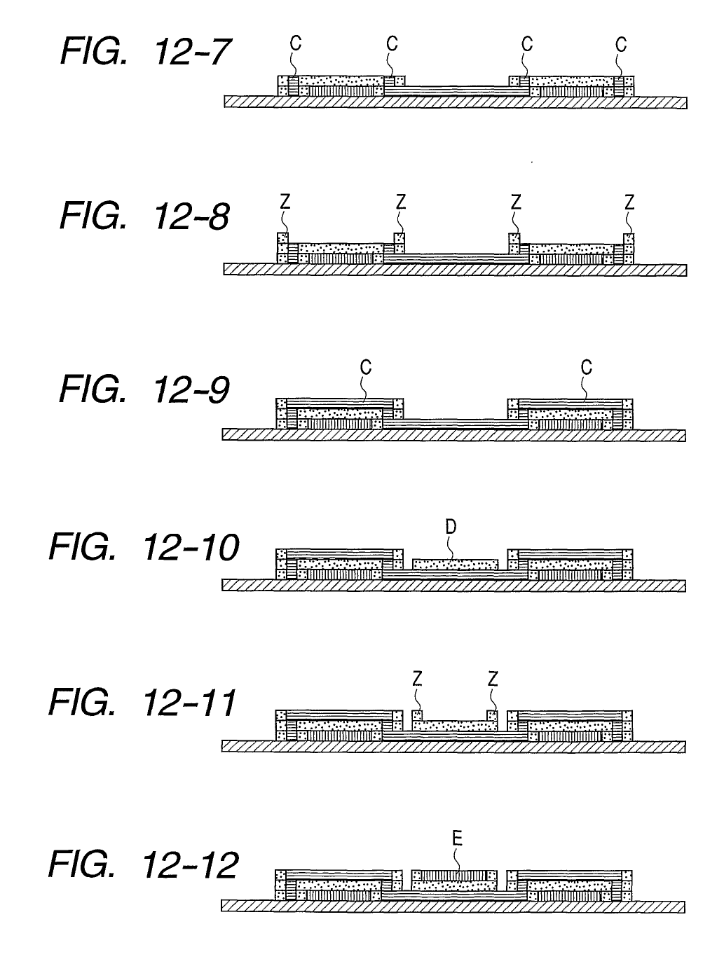

In the present example, an example will be described in which the wiring of Example 2 is formed in accordance with mask information. FIGS. 11-1 to 11-6, 12-7 to 12-12 are diagrams showing wiring forming steps according to one of the embodiments of the present invention. This method is different from the wiring forming method of Example 3 described with reference to FIGS. 9-1 to 9-7, 10-8 to 10-11 only in that insulated patterns are formed on opposite sides of each conductive pattern. Therefore, description of the forming method will be omitted. As compared with Example 3, the conductive pattern on an outermost side can be inhibited from being spread. Therefore, even when another wiring is formed in the vicinity of the present wiring pattern, the wiring having high reliability can be formed without any short-circuit of the wiring.

### EXAMPLE 5

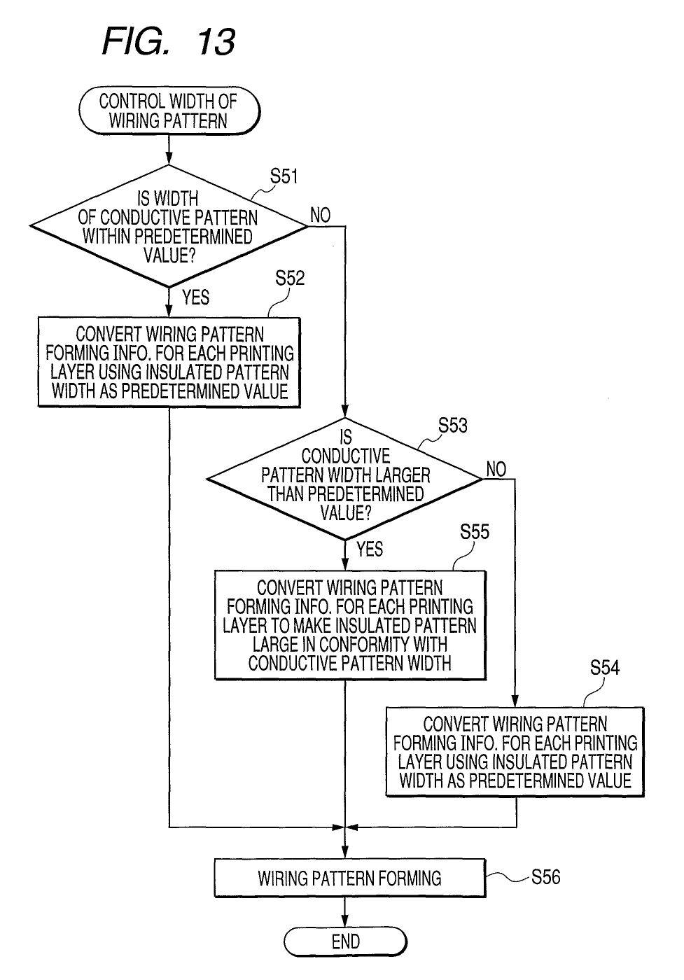

FIG. 13 is a flowchart showing control of a size of an insulated pattern in conformity with the size of the corresponding conductive pattern. When a conductive pattern width is larger than a certain width, the width of the insulated pattern to an adjacent pattern is constitute to be large in consideration of a current flowing through the pattern or the like.

Any of Examples 1 to 4 may be used concerning a wiring pattern forming method.

It is judged in step S51 whether or not a pattern width larger than a predetermined value exists in a conductive pattern in wiring pattern information which is to form a wiring pattern. Here, in the case of the pattern having the predetermined value only, in step S52, the width of the insulated pattern is set to the predetermined value, and calculation is executed in such a manner as to convert wiring pattern forming information for each printing layer. When the conductive pattern width having a value other than the predetermined value is included in the step S51, it is judged in step S53 whether the width of the conductive pattern having the value other than the predetermined value is larger/smaller than the predetermined value. When there is a conductive pattern smaller than the predetermined value, in step S54, the calculation is executed in such a manner as to convert the wiring pattern forming information using the width of the insulated pattern as the predetermined value. When there is a conductive pattern larger than the predetermined value, in step S55, the wiring pattern forming information is converted for each printing layer in such a manner as to form a large width of the insulated pattern in conformity with the width of the conductive pattern. In step S56, the wiring pattern is formed on the substrate in accordance with the insulated pattern information and the conductive pattern information, and the forming of the wiring pattern is completed.

The present invention is not limited to the conductive pattern width and the insulated pattern width. To change a height of the pattern, it has been considered that a discharge amount of a wiring pattern forming liquid is increased in forming the wiring pattern, and the conductive and insulated patterns are extended upwards. It has been described that the above-described process is executed on the side of the wiring forming apparatus after receiving the printing layer information, but the present invention is not limited to this. Various information is distinguished when received, and the information may be received as the printing layer information converted into data having a format in accordance with the process.

### EXAMPLE 6

In the present example, a procedure for performing a heating/curing process after forming a wiring pattern will be described.

After forming an insulated pattern on a substrate, the insulated pattern formed on the substrate is cured through a heating/curing device. Thereafter, a conductive pattern is formed, and cured again through the heating/curing. Accordingly, the cured insulated pattern functions as an edge of the conductive pattern, a wiring is prevented from being short-circuited by contact between the conductive patterns, and the wiring having high reliability can be formed. Various heating procedures are applicable to each printing layer or each mask pattern without departing from the scope of the present invention.

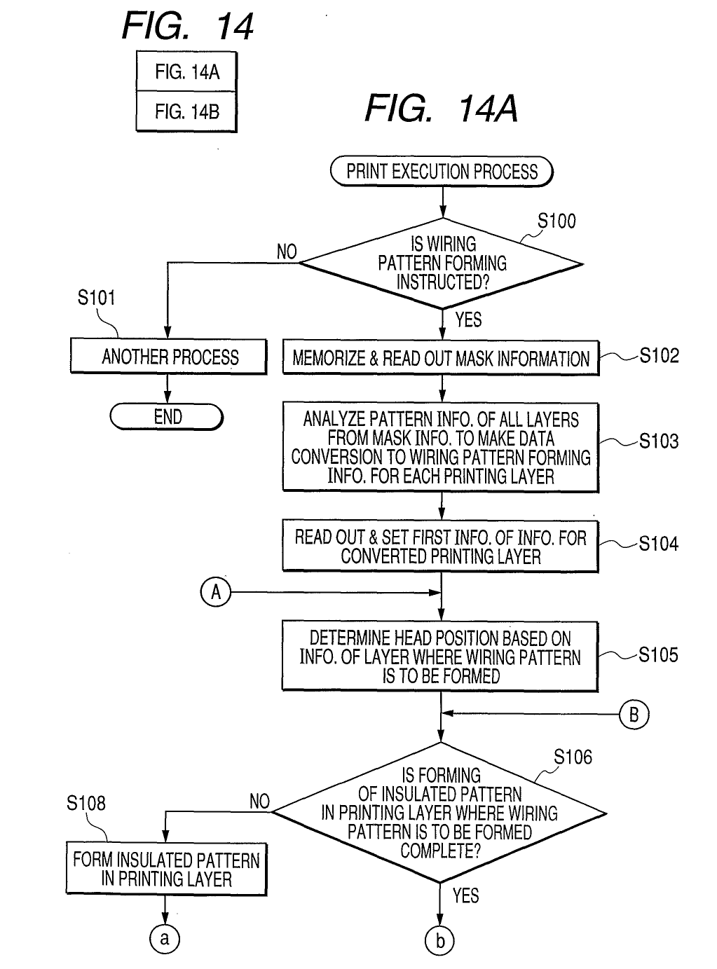

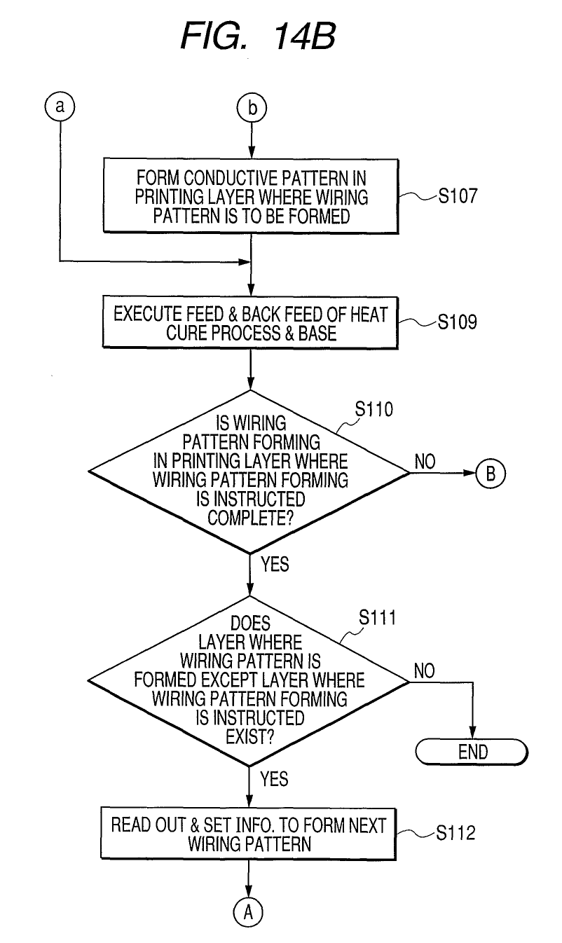

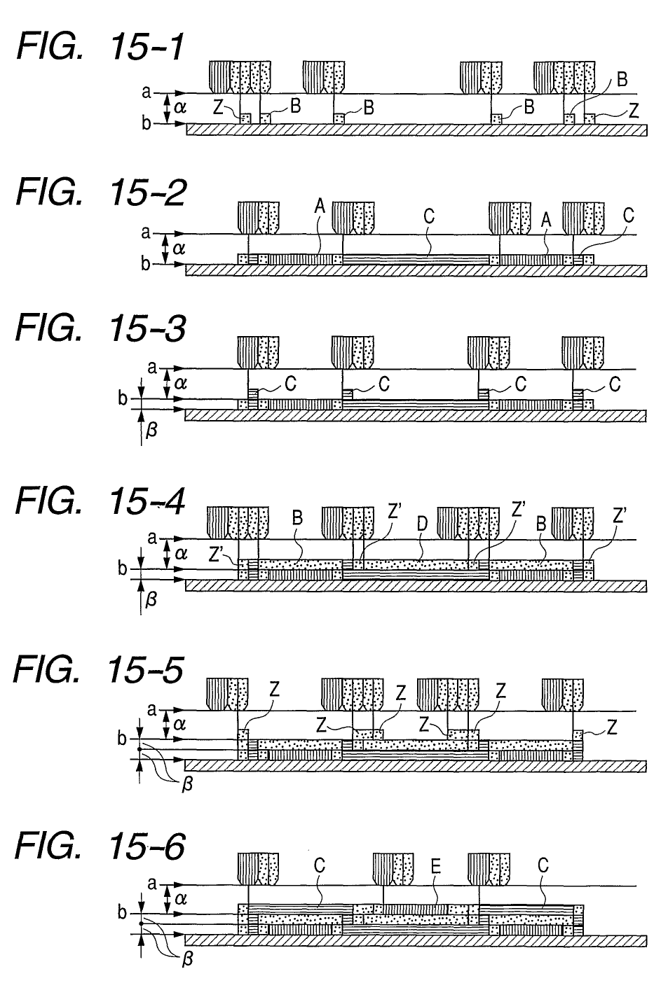

In the present example, after forming all the insulated patterns corresponding to a first layer of a printing layer with respect to the substrate, a heating process is performed, thereafter the conductive pattern of the first layer of the printing layer is formed, and the wiring pattern is formed for each printing layer. FIGS. 14A and 14B are flowcharts showing a procedure to perform a heating/curing process of the wiring pattern. In FIG. 14A, it is judged in step S100 whether or not the forming of the wiring pattern has been instructed. When there is not any wiring pattern forming instruction, another process is executed and completed in step S101. When there is a wiring pattern forming instruction, the data (mask information for semiconductor printing in the present example) instructed to be formed is read out and stored in a memory in step S102. In step S103, wiring pattern information of all layers is analyzed from the acquired mask information, and the data is converted into wiring pattern forming information for each printing layer. Here, the converted information is stored in memory means of a main body, and the wiring pattern is formed based on the wiring pattern forming information for each printing layer. In step S104, the wiring pattern forming information to be first executed is read out from the information for each printing layer, which was converted in the step S103, and the data is set. In step S105, the position of the head is determined based on the wiring pattern forming information of a layer where the wiring pattern is to be formed. It is judged in step S106 whether or not an insulated pattern in the printing layer where the wiring pattern is to be formed has been formed. When the forming of the insulated pattern is completed, the step jumps to step S107, and the conductive pattern in the printing layer where the wiring pattern is to be formed is formed. When the insulated pattern remains in the printing layer, the process advances to step S108, and the insulated pattern in the printing layer is formed. In step S109, a heat cure process and a base are fed and fed back with respect to the wiring pattern formed on the substrate. It is judged in step S110 whether or not there is a wiring pattern in the printing layer in which the wiring pattern has been instructed to be formed. When there is still the wiring pattern, the process returns to the step S106. When the forming of the wiring pattern in the printing layer where the wiring pattern has been instructed to be formed is completed, the process advances to step S111. It is judged in the step S111 whether or not the layer where the wiring pattern is to be formed exists except the printing layer where the wiring pattern has been instructed to be formed. When the forming of the wiring pattern is completed in all layers, the output of the printing information is completed. When the printing layer exists, the process advances to step S112, printing pattern information for forming the next wiring pattern is read out from information obtained in the step S103, the data is set, and the process returns to the step S105. When this flow is continued, the wiring pattern constituted of the conductive and insulated patterns is formed on the substrate.

### EXAMPLE 7

In the present example, an example will be described in which an order of an insulated pattern forming step and a conductive pattern forming step is changed in accordance with information of a wiring pattern formed on a substrate to form a wiring.

FIGS. 15-1 to 15-6 are diagrams showing the wiring forming steps according to one of embodiments of the present invention. Insulated and conductive patterns are schematically shown in such a manner as to clarify a structure of lamination of the patterns. As a method of controlling a discharge port surface of a head and a wiring pattern forming surface, a method shown in FIGS. 4A to 4C or FIGS. 5A, 5B is used. Conductive patterns A and C, and insulated patterns B, D, and Z shown in FIGS. 15-1 to 15-6 are formed in the same manner as in Example 2.

In FIG. 15-1, to form a wiring pattern of a first layer of a printing layer, the insulated patterns B and Z are formed in the vicinity of positions where the conductive patterns are to be formed.

In FIG. 15-2, after finishing the forming of the insulated patterns, the conductive patterns C and A are formed between the insulated patterns. The present example is the same as Example 2 up to this step.

In FIG. 15-3, the conductive patterns C in a second layer of a printing layer function as through holes which connect the conductive pattern of the first layer to that of a third layer. The conductive pattern for the through hole is formed prior to the insulated pattern in the printing layer in which the conductive pattern forming the through hole exists. Accordingly, since the conductive pattern forming the through hole is securely connected to the conductive patterns of upper/lower printing layers, in FIG. 15-3, the conductive patterns C in the second layer of the printing layer are formed prior to the insulated patterns in the same layer.

In FIG. 15-4, insulated patterns B, D, and Z′ are formed. The insulated pattern Z′ is formed after the conductive pattern. Here, since the conductive pattern does not exist between the insulated pattern D and the insulated pattern Z′ adjacent to the insulated pattern D at a certain distance, two insulated patterns are linked and formed.

In FIG. 15-5, the insulated pattern Z is formed in a third layer of the printing layer. Here, since the insulated patterns Z exist adjacent to each other at a certain distance, the respective insulated patterns are linked and formed.

In FIG. 15-6, conductive patterns C and a conductive pattern E are formed.

As described above, the order of the insulated pattern forming step and the conductive pattern forming step is appropriately changed in accordance with the information of the wiring to be formed on the substrate, and accordingly the wiring does not short-circuit in the first layer of the printing layer. In the second layer of the printing layer, and subsequent layers, the conductive pattern functioning as a through hole conducts with respect to upper/lower conductive patterns, the wiring can be prevented from being short-circuited in a wiring portion except the through hole, and it is possible to prepare a wiring board having a higher reliability.

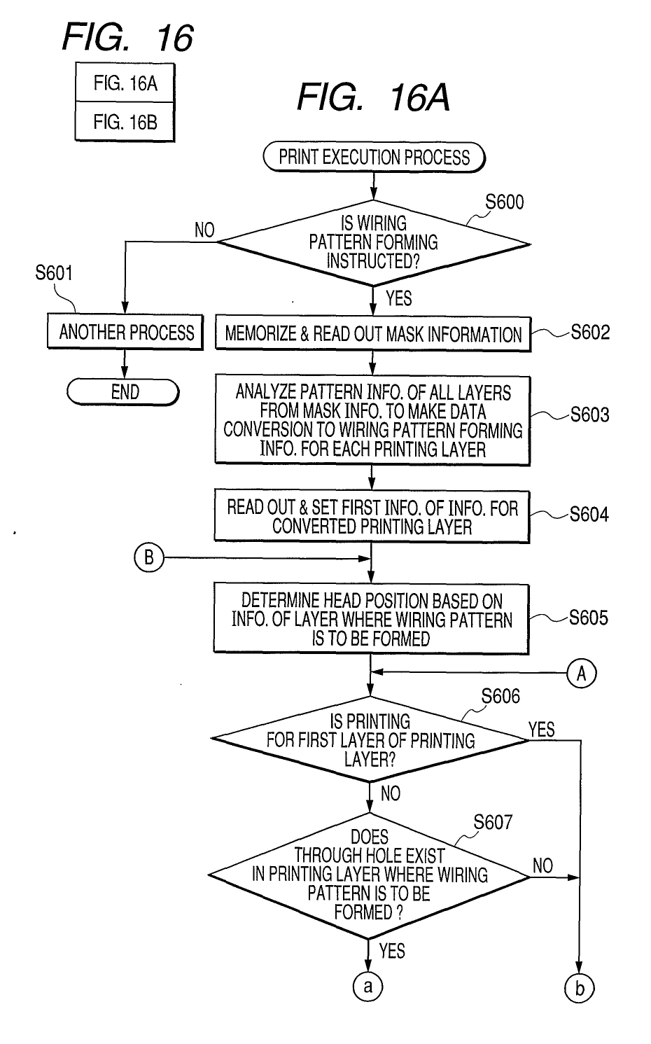

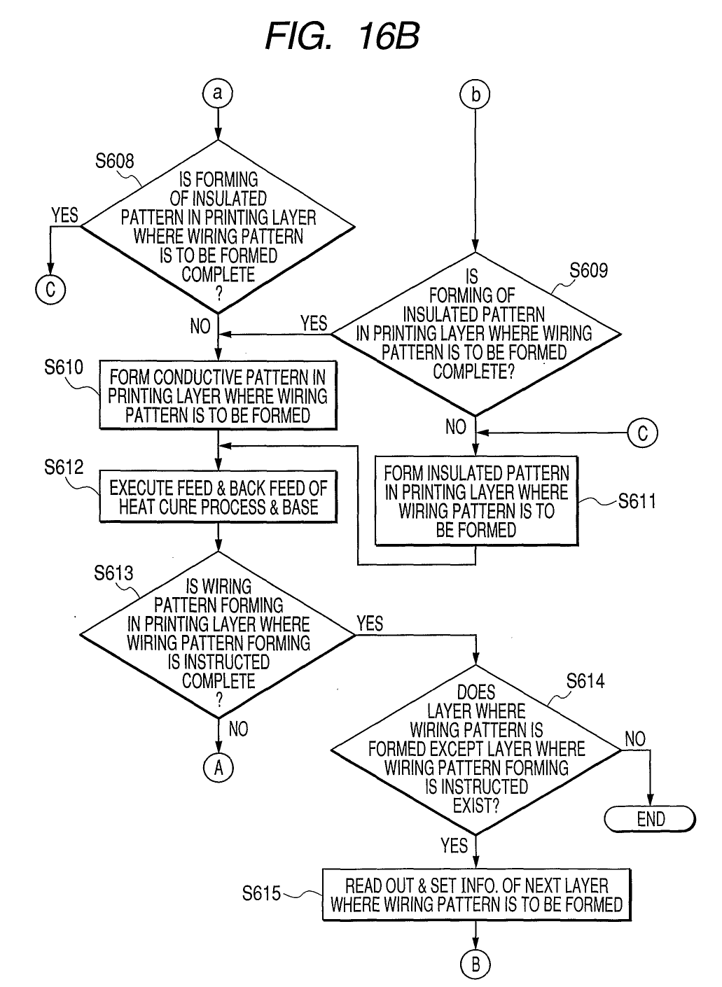

FIGS. 16A and 16B show flowcharts showing a procedure for performing a heating/curing process of a wiring pattern. It is judged in step S600 in FIG. 16A whether or not the forming of the wiring pattern has been instructed. When there is not any wiring pattern forming instruction, another process is executed and completed in step S601. When there is a wiring pattern forming instruction, the data (mask information for semiconductor printing in the present example) instructed to be formed is read out and stored in a memory in step S602. In step S603, wiring pattern forming information of all layers is analyzed from the acquired mask information, and the data is converted into the wiring pattern forming information for each printing layer. The information converted here is stored in memory means of a main body, and the wiring pattern is formed based on the wiring pattern forming information for each printing layer. In step S604, the wiring pattern forming information to be first executed is read out from the information for each printing layer, which was converted in the step S603, and the data is set. In step S605, the position of the head is determined based on the wiring pattern forming information of a layer where the wiring pattern is to be formed. It is judged in step S606 whether or not the printing layer where the wiring pattern is to be formed is the first layer of the printing layer.

When there is an instruction to form the wiring pattern in the first layer of the printing layer in the step S606, the process advances to step S609. It is judged in the step S609 whether or not the forming of the insulated pattern in the printing layer where the wiring pattern is to be formed has been completed. When the forming of the insulated pattern is not completed, the insulated pattern is formed in step S611, and a heat cure process of the insulated pattern and a base are fed and fed back in step S612. When the forming of the insulated pattern is completed, the process advances to step S610, the conductive pattern is formed, and a heat effect process or the like of the conductive pattern is performed in step S612.

When the first layer of the printing layer is not printed in the step S606, the process advances to step S607. It is judged in the step S607 whether or not the wiring pattern information for forming through holes in a printing layer where the wiring pattern is to be formed is included.

When any through hole does not exist in the printing layer where the wiring pattern is to be formed, the process advances to step S609. When the through hole exists in the printing layer where the wiring pattern is to be formed, the process advances to step S608. It is judged in the step S608 whether or not the forming of the conductive pattern in the printing layer where the wiring pattern is to be formed has been completed. When the forming of the conductive pattern in the printing layer wherein the wiring pattern is to be formed is not completed, the process advances to the step S610, and the conductive pattern is formed. When the forming of the conductive pattern in the printing layer where the wiring pattern is to be formed is completed, the process advances to step S611 to form the insulated pattern.

The heat effect process of the conductive pattern is performed in step S612, and it is judged in step S613 whether or not all wiring patterns in the printing layer where the wiring pattern is instructed to be formed have been formed. When the wiring pattern has not been formed, the process returns to step S606. When the wiring pattern has been formed, the process advances to step S614.

It is judged in step S614 whether or not the printing layer exists except the printing layer where the wiring pattern is instructed to be formed. When the wiring patterns have been formed in all the layers, the output of the printing information ends. When the printing layer exists, the process advances to step S615, printing pattern forming information for forming the next wiring pattern is read out from information obtained in the step S603, and the process returns to step S604. When this flow is continued, the wiring pattern constituted of the insulated and insulated patterns is formed on the substrate.

### EXAMPLE 8

In Example 7, the example has been described in which the conductive pattern is formed prior to the insulated pattern in the same layer in the printing layer having the conductive pattern forming the through hole. In the present example, an example will be described in which the conductive pattern is formed prior to the insulated pattern in a case where there is the conductive pattern contacting the conductive pattern in a layer under the conductive pattern in the printing layer to be printed.

FIGS. 17-1 to 17-7 are diagrams showing wiring forming steps according to one of embodiments of the present invention.

As a method of controlling a discharge port surface of a head and a wiring pattern forming surface, a method shown in FIGS. 4A to 4C or FIGS. 5A, 5B is used. Conductive patterns A and C, and insulated patterns B, D, and Z shown in FIGS. 17-1 to 17-7 are formed in the same manner as in Example 2.

In FIG. 17-1, to form the wiring pattern of a first layer of a printing layer, insulated patterns B and Z are formed in the vicinity of positions where the conductive patterns are to be formed.

In FIG. 17-2, after finishing the forming of the insulated patterns, conductive patterns C and A are formed between the insulated patterns.

In FIG. 17-3, the conductive patterns C of a second layer of the printing layer function as through holes which connect the conductive pattern of the first layer to that of a third layer. Since a conductive pattern contacting another conductive pattern exists in a layer under a conductive pattern to be formed, the conductive pattern is formed prior to the insulated pattern. Therefore, the conductive patterns C of the second layer of the printing layer are formed prior to the insulated patterns of the same layer, and accordingly the conductive patterns forming the through holes are securely connected to each other.

In FIG. 17-4, insulated patterns B, D, Z′ are formed. The insulated patterns Z′ are formed after the conductive patterns.

In FIG. 17-5, insulated patterns Z are formed around the conductive pattern of the third layer of the printing layer, which does not contact the conductive pattern of the lower printing layer.

In FIG. 17-6, a conductive pattern E is formed between the insulated patterns Z, and conductive patterns C of the third layer of the printing layer, which contact the conductive patterns of the lower printing layer, are formed.

In FIG. 17-7, insulated patterns Z′ are formed.

As described above, the order of the insulated pattern forming step and the conductive pattern forming pattern is appropriately changed in accordance with information of the wiring to be formed on the substrate. Accordingly, the wiring does not short-circuit in the first layer of the printing layer, the conductive patterns forming the through holes conduct with respect to the upper/lower conductive patterns in the second and subsequent layers of the printing layer, and the short-circuit of the wiring can be prevented in the wiring portion except the through hole. In the present invention, a wiring board having highest reliability can be prepared.

### EXAMPLE 9

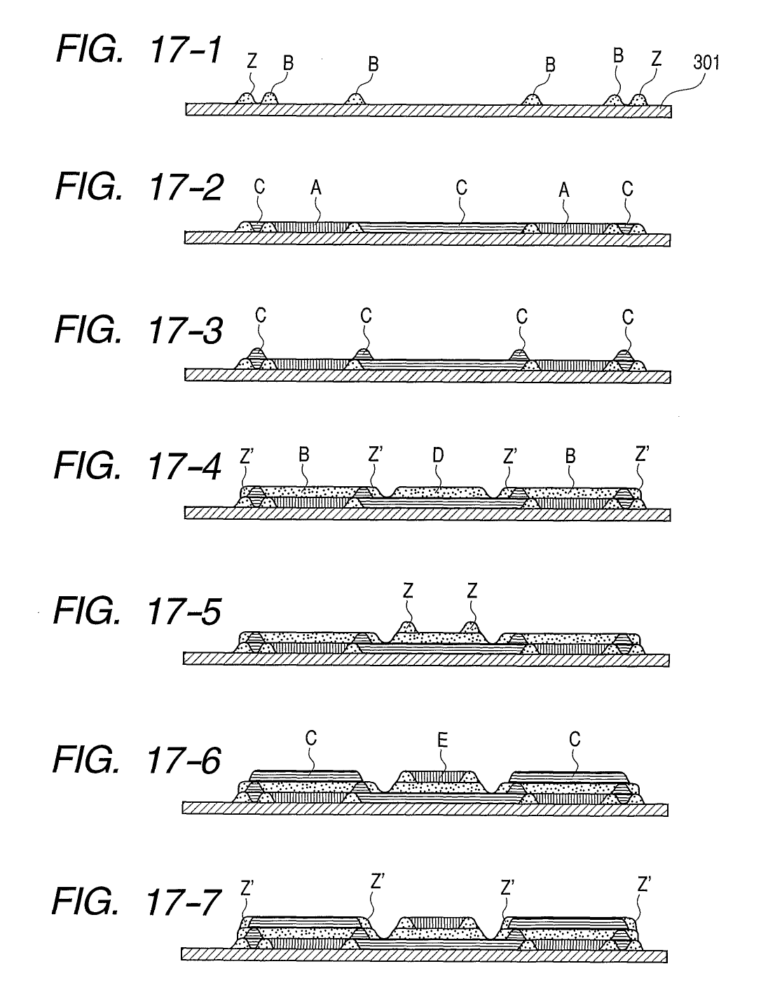

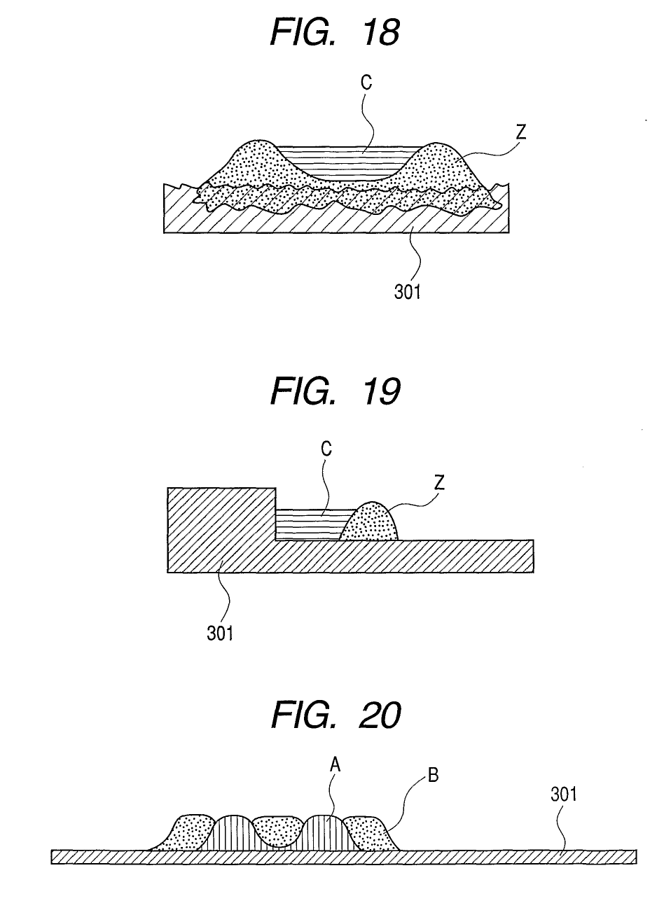

In the present example, FIGS. 18, 19 show that a wiring is formed on a substrate which does not have a flat surface.

FIG. 18 is a sectional view of a case where a wiring pattern is formed on a substrate (paper, cloth, etc.) having permeability. After forming a plurality of insulated patterns Z in such a manner that the patterns contact each other, a conductive pattern C is formed between concave portions between the insulated patterns in order to prevent precision of the wiring from being lowered by the conductive pattern C permeating in a substrate 301.

FIG. 19 is a sectional view of a case where the wiring pattern is formed on a substrate having a convex portion. An insulated pattern Z is formed beside the convex portion of the substrate 301, and a conductive pattern C is formed between the convex portion of the substrate and the insulated pattern. Accordingly, the conductive pattern is prevented from being spread. It is possible to form a high-reliability wiring in which a wiring does not short-circuit, even when another wiring is formed in the vicinity of the present wiring pattern.

In Examples 1 to 8, it has been described that all printing layer information is output every scanning of a head. It is also considered that after forming the insulated pattern corresponding to a printing layer for one page, the substrate is fed back and returned to an initial position of a printing apparatus, and the conductive pattern corresponding to the printing layer for one page is formed. It is apparent that a feeding type motor is driven in reverse to thereby form the wiring pattern, and accordingly an operation can be executed.

Furthermore, in Examples 1 to 8, the forming of the wiring pattern in one direction has been described, but the present invention is not limited to the examples, and can be executed by bidirectional printing. In Examples 1 to 8, it has been described that the wiring pattern is formed every designated pattern of a designated layer, but the present invention is not limited to the examples. For example, when portions having different heights exist in one scan of the head, pattern forming liquid droplets are output with respect to a portion having a height corresponding to one layer only once per scan. When a portion having a height corresponding to two layers exists, the scanning is performed twice to output the pattern forming liquid droplets once only with respect to a necessary portion. Furthermore, with respect to a portion of a third layer, pattern forming liquid droplets are output only with respect to a necessary portion three times in the same manner.

### EXAMPLE 10

A coil constituted of a conductive pattern or a capacitor constituted of a conductive pattern and an insulated pattern is formed according to the present invention, and accordingly a non-contact radio frequency identification (RFID) chip can be formed. Furthermore, when a transistor, a diode and the like are formed, as a wiring pattern forming liquid, besides the above-described second liquid forming the conductive pattern and the first liquid forming the insulated pattern, as a third liquid, a liquid containing inorganic materials such as Si and Ge or organic materials such as amine, hydrazone, stilbene, and starbust-based materials, and forming a semiconductor pattern is used. As a fourth liquid, a material such as an adhesive layer for fixing a wiring pattern is used if necessary. Accordingly, an electronic element may be formed. Here, a step of forming the semiconductor pattern is performed in the same manner as in the above-described conductive pattern forming step. The order of the semiconductor pattern forming step and the insulated pattern forming step is changed, and the semiconductor pattern having high reliability can be formed.

### EXAMPLE 11

In the present example, an example in which an organic EL is prepared using insulated patterns having different properties.

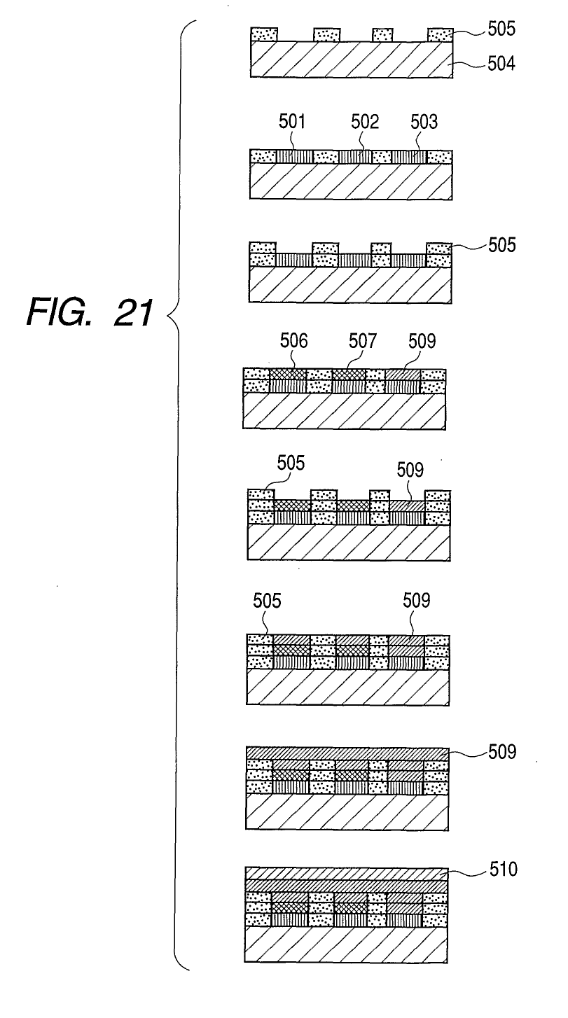

As shown in FIG. 21, a resist 505 having a structure functioning both as a light interrupting layer and an ink drop preventive wall is formed on a glass substrate 504. The resist preferably has a width of 20 microns, and a thickness of about 1.0 micron. When the thickness of one micron is not obtained by one discharge, the discharging is performed a plurality of times. First, the resist 505 is discharged as a pattern of a first layer. Next, liquids 501, 502, and 503 forming transparent pixel electrodes are discharged between the resists 505 in such a manner as to form a pattern having a thickness of about 0.1 micron, for example, while jetting ink at a 100-micron pitch.

Subsequently, the resist is discharged again in order to increase the height of the resist 505. A PPV precursor which is a light emitting material forming an insulated pattern is discharged onto the transparent electrode between the resists, and color-producing layers 506, 507 each having a thickness of about 0.05 micron are formed. Thereafter, a polymer precursor is formed into a polymer by a heating process, and the light emitting layers 506, 507 are formed. Next, an aluminum quinolinole complex is formed into a charge transport type light emitting layer 509 having a thickness of 0.1 micron. Finally, an MgAg reflective electrode 510 having a thickness of 0.1 to 0.2 micron is formed by an ink jet method, and an organic EL display member is completed.

As described above, various applications are possible without departing from the scope of the present invention.

This application claims priority from Japanese Patent Application No. 2003-424990 filed Dec. 22, 2003, which is hereby incorporated by reference herein.

1. A wiring forming method of supplying a first liquid and a second liquid in such a manner that said first liquid and said second liquid contact with each other on a substrate to thereby form a wiring pattern including the first pattern and the second pattern on the substrate, the method comprising:
a first pattern forming step of supplying the first liquid to thereby form the first pattern on the substrate: and
a second pattern forming step of supplying the second liquid to thereby form the second pattern on the substrate,
wherein a forming order of said first pattern and said second pattern for constituting said writing pattern in a same layer is changed in accordance with information of said wiring pattern.

2. (canceled)

3. The wiring forming method according to claim 1, wherein curing process is performed each time said first pattern or said second pattern is formed to the substrate.

4. (canceled)

5. The wiring forming method according to claim 1, wherein the first pattern forming step comprises the steps of: forming the first patterns on a plurality of positions of the substrate, and thereafter the second pattern forming step comprises the steps of: forming the second pattern between the first patterns formed in the plurality of positions on the substrate in such a manner as to bring the second pattern into contact with the first pattern.

6. The wiring forming method according to claim 1, further comprising the steps of: discharging the first and second liquids by an ink jet system to thereby supply the liquids onto the substrate.

7. (canceled)

8. The wiring forming method according to claim 1, wherein the first pattern is an insulated pattern having an insulating property, and the second pattern is a conductive pattern having conductivity.

9. The wiring forming method according to claim 1, wherein the first and second patterns are insulating insulated patterns having different properties.

10. The wiring forming method according to claim 1, wherein the first pattern is an insulated pattern having an insulating property, and the second pattern is a semiconductor pattern of a semiconductor.

11. A wiring board comprising: a wiring formed by the wiring forming method according to claim 1; and the substrate.

12. A wiring forming apparatus for supplying a first liquid forming a first pattern and a second liquid forming a second pattern in such a manner that the first liquid and the second liquid contact with each other on a substrate to there form a wiring pattern including said first pattern and said second wiring pattern on the substrate, the apparatus comprising:
a first liquid container which stores the first liquid;
a second liquid container which stores the second liquid;
first pattern forming means for supplying the first liquid on the substrate from the first liquid container to thereby form the first pattern;
second pattern forming means for supplying the second liquid on the substrate form the second liquid container to thereby form the second pattern; and
means for changing a forming order of said first pattern formed by using said first pattern forming means and said second pattern formed by using said second forming means in accordance with information of said wiring pattern upon forming said siring pattern in a same layer.

13-15. (canceled)

16. The wiring forming apparatus according to claim 12, wherein a size of the corresponding first pattern is changeable in accordance with that of the second pattern to be formed.

17-19. (canceled)
